(19) United States
(12) Patent Application Publication
(10) Pub. No.: US 2018/0248063 A1
(43) Pub. Date: Aug. 30, 2018

(54) HYBRID CONCENTRATED PHOTOVOLTAIC DEVICE

(71) Applicant: ENI S.P.A., Roma (IT)

(72) Inventors: Roberto FUSCO, Novara (IT); Lucio ANDREANI, Pavia (IT); Angelo BOZZOLA, Brescia (IT); Davide COMORETTO, Milano (IT); Valentina ROBBIANO, Ovada (IT); Michele LAUS, Alessandria (IT); Katia SPARNACCI, Alessandria (IT)

(21) Appl. No.: 15/542,452

(22) PCT Filed: Jan. 26, 2016
(86) PCT No.: PCT/EP2016/051557

§ 371 Date: Jul. 10, 2017

(30) Foreign Application Priority Data
Jan. 27, 2015 (IT) MI2015A000091

(51) Int. Cl. H01L 31/055; H01L 31/054; C09K 11/06

(52) U.S. Cl. CPC H01L 31/055; H01L 31/0543; B82Y 30/00; C09K 11/06; H01L 31/0547

(57) ABSTRACT

Hybrid concentrated photovoltaic device comprising: (i) at least one luminescent solar concentrator (LSC) having the shape of a polygonal, circular, or elliptical plate, comprising at least one photoluminescent compound having a spectral range of absorption and a spectral range of emission; (ii) at least one micrometric or sub-micrometric dielectric photonic structure, optically coupled to said luminescent solar concentrator (LSC), said micrometric or sub-micrometric dielectric photonic structure being able to induce diffusion and/or diffraction of sunlight, preferably diffraction, within said luminescent solar concentrator (LSC), in a spectral range where there is no absorption of said photoluminescent compound; (iii) at least one photovoltaic cell positioned on the outside of at least one side of said luminescent solar concentrator (LSC). The aforementioned hybrid concentrated photovoltaic device may advantageously be incorporated in buildings and dwellings (for example, in photovoltaic glass doors, in photovoltaic skylights, in photovoltaic windows, both indoor and outdoor). Moreover, said hybrid concentrated photovoltaic device may also be used advantageously as a functional element in urban and transport contexts (for example, in photovoltaic noise barriers, in photovoltaic windbreaks).

The present invention relates to a hybrid concentrated photovoltaic device. More particularly, the present invention relates to a hybrid concentrated photovoltaic device comprising: (i) at least one luminescent solar concentrator (LSC) having the shape of a polygonal, circular, or elliptical plate, comprising at least one photoluminescent compound having a spectral range of absorption and a spectral range of emission; (ii) at least one micrometric or sub-micrometric dielectric photonic structure, optically coupled to said luminescent solar concentrator (LSC), said micrometric or sub-micrometric dielectric photonic structure being able to induce diffusion and/or diffraction, preferably diffraction of sunlight within said luminescent solar concentrator (LSC), in a spectral range where there is no absorption of said photoluminescent compound; (iii) at least one photovoltaic cell positioned on the outside of at least one side of said luminescent solar concentrator (LSC).

The aforementioned hybrid concentrated photovoltaic device may advantageously be incorporated in buildings and dwellings (for example, in photovoltaic glass doors, in photovoltaic skylights, in photovoltaic windows, both indoor and outdoor). Moreover, said hybrid concentrated photovoltaic device may also be used advantageously as a functional element in urban and transport contexts (for example, in photovoltaic noise barriers, in photovoltaic windbreaks).

Said photovoltaic device has good efficiency, i.e. allows incident sunlight to be converted into electricity in a wide spectrum of wavelengths. In particular, for evaluating said efficiency, the solar spectrum “Air Mass” 1.5 G, reported on the website rredc.nrel.gov/solar/spectra/am1.5/, was used in the examples reported hereunder. The corresponding photon flux is of the order of 10¹⁴ photons×s⁻¹×cm⁻²×nm⁻¹, it extends over wavelengths ranging from 300 nm to 2500 nm, and has a maximum for wavelengths ranging from 600 nm to 800 nm.

For the purpose of the present description and of the claims that follow, the terms “photovoltaic device(s)”, “photovoltaic cell(s)” and “photovoltaic module(s)”, and the terms “solar device(s)”, “solar cell(s)” and “solar module(s)”, may be used synonymously. It is known that photovoltaic devices are only able to convert a portion of the incident sunlight into electricity. The ability of photovoltaic devices to convert and collect photogenerated charge carriers (i.e. photogenerated electron-hole pairs) is expressed by their external quantum efficiency (EQE), defined as the ratio between the number of electron-hole pairs generated in the semiconductor material of the photovoltaic device and the number of incident photons on the photovoltaic device. For example, photovoltaic modules based on silicon wafers have an external quantum efficiency (EQE) close to 1 for wavelengths ranging from about 350 nm to 1000 nm. The upper limit of said interval is imposed by the electronic gap of silicon that defines the onset of absorption.

Numerous examples of photovoltaic devices have been proposed in the past. Said photovoltaic devices may be subdivided into four main categories:
(1) photovoltaic modules obtained by connecting together several conventional photovoltaic cells based on inorganic semiconductor materials (for example, silicon) (opaque), leaving suitable openings or holes through which a portion of the sunlight may pass and illuminate the underlying environment;
(2) photovoltaic cells based on organic semiconductor materials, typically an organic polymer;
(3) solar concentrators based on transparent waveguides, inside which light-diffusing materials are arranged, or suitable partially reflecting internal faces, capable of directing a portion of the incident light onto photovoltaic cells arranged at the ends of said waveguides;
(4) luminescent solar concentrators (LSCs).

Said photovoltaic devices, as shown below, have some drawbacks such as, for example:
transparency or semi-transparency limited to just some zones of the device, while the others are opaque;
an external quantum efficiency (EQE) limited to a narrow range of wavelengths, typically a range of the visible spectrum.

Photovoltaic devices belonging to category (1) are described, for example, in American patents U.S. Pat. No. 5,176,758 and U.S. Pat. No. 5,254,179. Said devices are able to utilize a wide range of wavelengths of incident light: however, their final external quantum efficiency (EQE) is limited by the semiconductor material used in the opaque zones of said device. Photovoltaic devices belonging to category (2) are described, for example, by Wörle D. et al., in “Advanced Materials” (1991), Vol. 3, Issue 3, p. 129-138; Günes S. et al., in “Chemical Reviews” (2007), Vol. 107, p. 1324-1338; Li G. et al., in “Nature Photonics” (2012), Vol. 6, p. 153-161. The band gap (i.e. the difference between the HOMO and LUMO orbitals of the organic compound used in said photovoltaic devices) of many organic compounds is in the visible and therefore makes said organic compounds semitransparent. In these cases, the external quantum efficiency (EQE) is limited to wavelengths in the visible less than that of the band gap.

Photovoltaic devices belonging to category (3) are described, for example, in American patents U.S. Pat. No. 4,733,929, U.S. Pat. No. 4,799,748, U.S. Pat. No. 6,021,007. In the aforementioned patents, in which the use of transparent waveguides is described, the processes of diffusion and/or diffraction of light are not coupled to luminescence.

The fourth category of photovoltaic devices relating to luminescent solar concentrators (LSCs) is of particular interest for the purpose of the present invention. As is known, the base unit of the luminescent solar concentrator (LSC), in the simplest form, comprises two elements:
a plate of plastic or vitreous transparent material, of polygonal, circular or elliptical shape, within which or in optical contact with which at least one photoluminescent compound is placed, characterized by a spectral range of absorption of sunlight and by a spectral range of emission of light;
one or more photovoltaic cells applied on at least one side of said plate for converting light guided there into electrical energy.

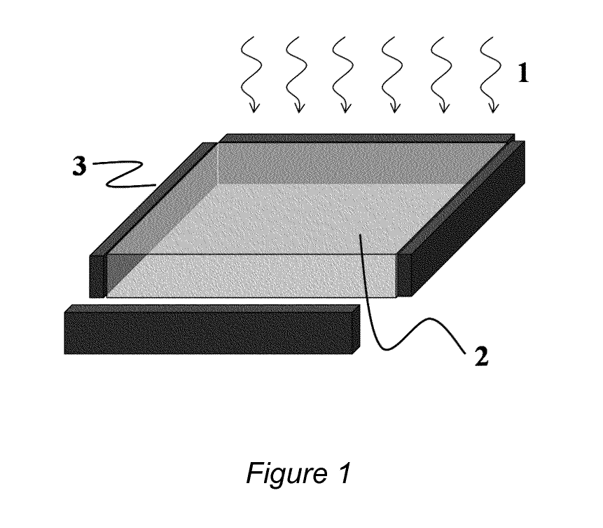

A schematic representation of a luminescent solar concentrator (LSC) having the configuration described above is shown in FIG. 1. In said FIG. 1, sunlight (1) is incident on the upper face of the plate of transparent material (2). The photoluminescent compound dispersed in said plate absorbs a portion of the incident spectrum, and emits light by photoluminescence within it. If the photons are not emitted within the exit cones (defined by the condition of total internal reflection) they may be propagated inside the plate, until they reach the photovoltaic cells (3) applied on the sides thereof.

Further information concerning the general characteristics of luminescent solar concentrators (LSCs) may also be found, for example, in the following documents: Weber W. H. et al., in “Applied Optics” (1976), Vol. 15, No. 10, p. 2299-2300; Levitt J. A. et al., in “Applied Optics” (1977), Vol. 16, Issue 10, p. 2684-2689; Reisfeld R. et al., in “Nature” (1978), Vol. 274, p. 144-145; Batchelder J. S. et al., in “Applied Optics” (1979), Vol. 18, Issue 18, p. 3090-3110 and in “Applied Optics” (1981), Vol. 20, Issue 21, p. 3733-3754; Earp A. A. et al., in “Solar Energy” (2004), Vol. 76, p. 655-667.

Owing to their semi-transparency and the possibility of collecting light on relatively large areas (up to 1 m²), luminescent solar concentrators (LSCs) may be used advantageously as building integrated devices as described for example by Debije M. G., in “Advanced Functional Materials” (2010), Vol. 20, No. 9, p. 1498-1502, and in “Advanced Energy Materials” (2012), Vol. 2, p. 12-35.

The use of luminescent solar concentrators (LSCs) in the construction sector is further facilitated by the possibility of using rigid and curved plates, as described, for example, in American patents U.S. Pat. No. 4,227,939 and U.S. Pat. No. 8,324,497. Curved plates may be obtained using flexible plastics as described, for example, by Buffa M. et al., in “Solar Energy Materials & Solar Cells” (2012), Vol. 103, p. 114-118; Fisher M. et al., in “Proceedings of the 38th IEEE Photovoltaic Specialists Conference (PVSC)” (2011), Austin, USA, 3-8 June, p. 003333-003338.

If photovoltaic cells are not applied on the sides of the plate of the luminescent solar concentrator (LSC), the light collected may be directed elsewhere by suitable transparent waveguides or optical fibres, and used for lighting interiors, as described, for example, by Earp A. A. et al., in “Solar Energy Materials & Solar Cells” (2004), Vol. 84, p. 411-426; Wang C. et al., in “Energy and Buildings” (2010), Vol. 42, Issue 5, p. 717-727.

For the use of luminescent solar concentrators (LSCs) in photovoltaic devices, their constituent components, i.e. plate, photoluminescent compound, and photovoltaic cell(s), should possess some characteristics that are not always mutually compatible.

In the first place, the material of the plate must be “perfectly” transparent, with a high refractive index (for the purpose of increasing the fraction of light guided by total internal reflection), and optically homogeneous, so as not to induce diffusion of the light during propagation within it. Usually the material of the plate may be selected, for example, from: transparent polymers such as, for example, polymethyl methacrylate (PMMA), polycarbonate (PC), polyisobutyl methacrylate, polyethyl methacrylate, polyallyl diglycol carbonate, polymethacrylimide, polycarbonate ether, styrene acrylonitrile, polystyrene (PS), methylmethacrylate styrene copolymers, polyether sulphone, polysulphone, cellulose triacetate, or mixtures thereof; transparent glasses such as, for example, silica, quartz, alumina, titania, or mixtures thereof. Generally, the photoluminescent compounds, in the case when the plate is made of polymeric material, are dispersed uniformly within the polymeric material of the plate. Alternatively, the photoluminescent compounds may be deposited on said plate, in the form of a thin film, as described, for example, by Rowan B. C. et al., in “IEEE Journal of Selected Topics in Quantum Electronics” (2008) Vol. 14, No. 5, p. 1312-1322; and in U.S. Pat. No. 4,149,902.

The ideal characteristics that a photoluminescent compound should possess are also multiple, and many lines of research target the synthesis of photoluminescent compounds at high efficiency.

In the first place, the photoluminescent compound should have a spectral range of emission that is at higher energy relative to the band gap of the semiconductor material that constitutes the core of the photovoltaic cell(s) applied on the side(s) of the luminescent solar concentrator (LSC). The optimum configuration is that where the spectral range of emission of the photoluminescent compound is at energy just higher than the band gap of said semiconductor material. This allows optimum energy transfer, and minimizes the non-radiative losses, as described, for example, by Sloff L. H. et al., in “Physica Status Solidi (RRL)-Rapid Research Letters” (2008), Vol. 2, Issue 6, p. 257-259.

Moreover, the photoluminescent compound should have an absorption spectrum that is as wide as possible, so as to absorb a large number of incident photons.

Photoluminescent materials that may be used advantageously for this purpose are, for example, organic compounds (for example, benzothiadiazole and derivatives thereof), metal complexes (for example, ruthenium complexes), and inorganic compounds (for example, rare earths). However, in all these cases, the absorption band only extends over a portion of the visible spectrum, limiting the external quantum efficiency (EQE) to a narrow wavelength range.

A possible alternative is represented by quantum dots (QDs), i.e. clusters of atoms of semiconducting material with characteristic dimensions of a few nanometres. Said quantum dots (QDs) are characterized by a wider range of absorption, which may be suitably defined in relation to the wavelengths of greatest interest by modifying their size. Examples of application of said quantum dots (QDs) in luminescent solar concentrators (LSCs) may be found in the following documents: Bomm J. et al., in “Solar Energy Materials & Solar Cells” (2011), Vol. 95, p. 2087-2094; Chandra S. et al., in “Solar Energy Materials & Solar Cells” (2012), Vol. 98, p. 385-390; Shcherbatyuk G. V. et al., in “Applied Physics Letters” (2010), Vol. 96, 191901.

Other important characteristics for the photoluminescent compound are its quantum yield of photoluminescence, which should be as close to 1 as possible, and the spectral overlap between the range of absorption and the range of emission, which must be reduced to the minimum. The self-absorption of the photoluminescence emitted by said photoluminescent compound depends on this last-mentioned characteristic. The process of self-absorption is analysed in detail in the following works: Sansregret J. et al., in “Applied Optics” (1983), Vol. 22, Issue 4, p. 573-577; Earp A. A. et al., in “Solar Energy Materials & Solar Cells” (2011), Vol. 95, p. 1157-1162; Flores Daorta S. et al., in “Proceedings of the 26th European Photovoltaic Conference and Exhibition” (2011), Hamburg, Germany, p. 264-267. Said process of self-absorption greatly limits the conversion efficiency of luminescent solar concentrators (LSCs) as their size is increased.

Generally, photoluminescent organic compounds allow to obtain high quantum yields of photoluminescence (up to 95%) and reduced spectral overlap between absorption bands and emission bands, but only operate in the visible; the rare earths are more stable over time relative to said photoluminescent organic compounds, but are more expensive, operate in the visible, and are characterized by lower quantum yields of photoluminescence (maximum 30%) relative to said photoluminescent organic compounds; quantum dots (QDs) also allow absorption of light in the near infrared (NIR) with wavelengths ranging from 700 nm to 1100 nm, but the quantum yield of luminescence is lower (about 70% maximum) relative to said photoluminescent organic compounds and the absorption and emission bands have a larger spectral overlap relative to said photoluminescent organic compounds.

For reducing the overlap between absorption bands and emission bands, it has been proposed to use compounds for resonance energy transfer (“Förster Resonance Energy Transfer”—FRET). In these compounds, a first chemical species absorbs sunlight and transfers the energy to a second chemical species, which emits it at lower energy. An example of application of said compounds is described by Bose R. et al., in “Proceedings of the 35th Photovoltaic Specialist Conference” (2010), Honolulu, USA, p. 000467-000470.

A further strategy for reducing the impact of the aforementioned self-absorption and for increasing the fraction of photoluminescence guided, is the use of anisotropic emitters. While the emitting compounds described in the article by Bose R. cited above have isotropic spatial emission, clusters of semiconducting material of elongated shape (“nanorods”) have anisotropic emission. Said clusters may be suitably aligned in a predefined direction, in such a way that emission of light preferably occurs outside the exit cones, thus increasing the fraction guided. The use of said materials in luminescent solar concentrators (LSCs) is illustrated, for example, in the following documents: Bose R. et al., in “Proceedings of the 33rd Photovoltaic Specialist Conference (PVSC)” (2008), San Diego, USA, p. 1-5; Verbunt P. P. C., in “Advanced Functional Materials” (2009), Vol. 19, Issue 17, p. 2714-2719; Debije M. G., in “Advanced Functional Materials” (2010), Vol. 20, p. 1498-1502; McDowall S. et al., in “Journal of Applied Physics” (2010), Vol. 108, 053508-1-053508-8; Mulder C. L. et al., in “Optics Express” (2010), Vol. 18, No. S1, p. A79-A90 and in “Optics Express” (2010), Vol. 18, No. S1, p. A91-A99; Farrell D. J. et al., in “Progress in Photovoltaics: Research and Applications” (2012), Vol. 20, p. 93-99. For the purpose of widening the absorption band of luminescent solar concentrators (LSCs), some strategies based on the use of several photoluminescent compounds having ranges of absorption at various wavelengths have been proposed in recent years. For example, Bailey S. T. et al., in “Solar Energy Materials & Solar Cells” (2007), Vol. 91, p. 67-75, described the use of three photoluminescent compounds in the same plate, obtaining an increase in current produced by a factor of 1.7 relative to the plate with only one photoluminescent compound.

A further possibility is provided by luminescent solar concentrators (LSCs) comprising several superposed plates, each of which is doped with a different photoluminescent compound. The final architecture is the optical analogue of a multijunction semiconductor photovoltaic cell, and is also known as a “Luminescent Spectrum Splitter” (LSS). The photoluminescent compound that absorbs at higher energy is used in the first plate (the one directly exposed to the sunlight), while the compounds that absorb at lower energy are dispersed in the underlying plates. Further information relating to said possibility may be found, for example, in the following documents: Earp A. A. et al., in “Solar Energy Materials & Solar Cells” (2004), Vol. 84, p. 411-426; Fisher B. et al., in “Solar Energy Materials & Solar Cells” (2011), Vol. 95, p. 1741-1755; Bozzola A. et al., in “Proceedings of the 26th European Photovoltaic Conference and Exhibition” (2011), Hamburg, Germany, p. 259-263.

The use of photonic structures and, more generally, of micro- and nanostructured materials has been proposed for improving the guidance properties of luminescent solar concentrators (LSCs). For example, distributed Bragg reflectors (DBRs), rugate filters, and mirrors with cholesteric liquid crystals, have been applied on the upper and lower faces of the luminescent solar concentrator (LSC) to limit the losses from the exit cones. In this case, the high reflectivity band of said photonic structures is centred on the emission band of the photoluminescent compound. The end result is a luminescent solar concentrator (LSC) with increased external quantum efficiency (EQE) in the absorption band (up to +20%) relative to the case without photonic structure. The application of the photonic structures as above to luminescent solar concentrators (LSCs) is illustrated, for example, in the following documents: Debije M. G. et al., in “Applied Optics” (2010), Vol. 49, Issue 4, p. 745-751; Gutmann J. et al., in “Optics Express” (2012), Vol. 20, No. S2, p. A157-A167; Goldschmidt J. C. et al., in “Physica Status Solidi (a)” (2008), Vol. 205, Issue 12, p. 2811-2821, and in “Proceedings of SPIE Photonics for Solar Energy Systems III” (2010), Vol. 7725, p. 77250S-1-77250S-11; van Sark W. G. J. H. M. et al., in “Optics Express” (2008), Vol. 16, No. 26, p. 21773-21792.

Photonic structures such as multilayers of dielectric spheres (opals) have been proposed for increasing the fraction of guided photoluminescence, and for modifying the angular emission of the photoluminescent compound, favouring coupling of the photoluminescence in the guided modes supported by the plate. Further information relating to the use of said photonic structures may be found, for example, in the following documents: Goldschmidt J. C. et al., in “Physica Status Solidi (a)” (2008), Vol. 205, Issue 12, p. 2811-2821; Gutmann J. et al., in “Proceedings of SPIE Photonics for Solar Energy Systems IV” (2012), Vol. 8438, p. 843810-1-843810-7.

It should be noted that all the photonic structures suitable for integration in luminescent solar concentrators (LSCs) mentioned above are characterized by a spectral range where they induce exclusively reflection of the emitted light, preventing the latter leaving the plate from the exit cones delimited by the condition of total internal reflection.

A further example of application of dielectric and metallic nanostructures for the purpose of increasing the absorption of the photoluminescent compound and of modifying its emission spectrum and relative directionality, is described in international patent application WO 2013/093696. However, these dielectric nanostructures are not designed for utilizing advantageously, and over a wide spectral range, the optical phenomena of diffusion and/or diffraction of light.

The use of colloidal photonic structures in photovoltaic devices is also known. For example, Mihi A. et al., in “The Journal of Physical Chemistry C” (2008), Vol. 112, p. 13-17, describe the use of porous structures based on opals or of multilayers of particles of opals in dye sensitized solar cells (DSSCs) for the purpose of localizing the electromagnetic field of the solar radiation in the region where the dye is distributed: in this way it is possible to intensify the absorption phenomenon, which is preparatory to the generation of current.

Mihi A. et al. in “Advanced Optical Materials” (2013), Vol. 1, p. 139-143, describe the use of monodispersed dielectric spheres applied to photovoltaic cells based on colloidal nanocrystals of PbS—TiO₂ capable of increasing the absorption of sunlight.

Films of opals with increased area have been prepared starting from monodisperse microspheres with “core-shell” structure by the melt compression technique as described, for example, by Ruhl T. et al., in “Polymer” (2003), Vol. 44, p. 7625-7634; or by spray deposition as described, for example, by Cui L. et al., in “Macromolecular Rapid Communications” (2009), Vol. 30, p. 598-603; or by printing in the presence of an electric field as described, for example, by Michaelis B. et al., in “Advanced Engineering Materials” (2013), Vol. 15, Issue 10, p. 948-953. Said structures also find application in films and coatings with unusual chromatic properties as described, for example, in the following documents: Pursiainen 0. L. J. et al., in “Optics Express” (2007), Vol. 15, No. 15, p. 9553-9561; Finlayson C. E. et al., in “Advanced Materials” (2011), Vol. 23, p. 1540-1544.

Despite the efforts noted above, investigation of hybrid concentrated photovoltaic devices able to utilize both phenomena of luminescence, and phenomena of diffusion and/or diffraction of sunlight, is still of great interest since these hybrid concentrated photovoltaic devices are able to utilize sunlight best, i.e. a wider portion of the solar spectrum. The applicant therefore undertook the task of producing a photovoltaic device capable both of extending the amplitude of the spectral response beyond the absorption and emission bands of the photoluminescent compound(s) present therein, and of increasing the current produced.

The applicant found that the use of at least one micrometric or sub-micrometric dielectric photonic structure optically coupled to at least one luminescent solar concentrator (LSC) on the sides of which at least one photovoltaic cell is placed, makes it possible to obtain a hybrid concentrated photovoltaic device able to have the aforementioned characteristics. Said hybrid concentrated photovoltaic device is based mainly on two optical mechanisms: (i) absorption of sunlight and subsequent emission by photoluminescence by the photoluminescent compound present in said luminescent solar concentrator (LSC), and (ii) diffusion and/or diffraction of the incident sunlight within said luminescent solar concentrator (LSC) by the aforementioned micrometric or sub-micrometric dielectric photonic structure: consequently, the photovoltaic cell(s) applied on at least one side of said luminescent solar concentrator (LSC) absorb(s) both the light emitted from the photoluminescent compound, and the light diffused and/or diffracted by said micrometric or sub-micrometric dielectric photonic structure, increasing the current produced. This hybrid concentrated photovoltaic device may advantageously be incorporated in buildings and dwellings (for example, in photovoltaic glass doors, in photovoltaic skylights, in photovoltaic windows, both indoor and outdoor). Moreover, said hybrid concentrated photovoltaic device may also be used advantageously as a functional element in urban and transport contexts (for example, in photovoltaic noise barriers, in photovoltaic windbreaks).

Therefore the present invention relates to a hybrid concentrated photovoltaic device comprising:
(i) at least one luminescent solar concentrator (LSC) having the shape of a polygonal, circular, or elliptical plate, comprising at least one photoluminescent compound having a spectral range of absorption and a spectral range of emission;
(ii) at least one micrometric or sub-micrometric dielectric photonic structure, optically coupled to said luminescent solar concentrator (LSC), said micrometric or sub-micrometric dielectric photonic structure being able to induce diffusion and/or diffraction of sunlight, preferably diffraction, within said luminescent solar concentrator (LSC), in a spectral range where there is no absorption of said photoluminescent compound;
(iii) at least one photovoltaic cell positioned on the outside of at least one side of said luminescent solar concentrator (LSC).

For the purpose of the present description and of the claims that follow, the definitions of numerical ranges always include the limits unless specified otherwise.

For the purpose of the present description and of the claims that follow, the term “comprising” also includes the terms “which consists essentially of” or “which consists of”.

For the purpose of the present description and of the claims that follow, the term “luminescent” is to be understood to refer to various possible phenomena of emission of light including, but not exclusively, fluorescence and phosphorescence.

According to a preferred embodiment of the present invention, said luminescent solar concentrator (LSC) comprises a matrix of transparent material that may be selected, for example, from: transparent polymers such as, for example, polymethyl methacrylate (PMMA), polycarbonate (PC), polyisobutyl methacrylate, polyethyl methacrylate, polyallyl diglycol carbonate, polymethacrylimide, polycarbonate ether, styrene acrylonitrile, polystyrene, methylmethacrylate styrene copolymers, polyether sulphone, polysulphone, cellulose triacetate, or mixtures thereof; transparent glasses such as, for example, silica, quartz, alumina, titania, or mixtures thereof. Polymethyl methacrylate (PMMA) is preferred.

For the purpose of the present invention, said at least one photoluminescent compound may be used in various forms.

For example, in the case when the transparent matrix is of the polymeric type, said at least one photoluminescent compound may be dispersed in the polymer of said transparent matrix by, for example, dispersion in the melt, or addition in the bulk, and subsequent formation of a plate comprising said polymer and said at least one photoluminescent compound, working, for example, by the so-called “casting” technique. Alternatively, said at least one photoluminescent compound and the polymer of said transparent matrix may be dissolved in at least one suitable solvent, obtaining a solution that is deposited on a plate of said polymer, forming a film comprising said at least one photoluminescent compound and said polymer, working, for example, by using a film applicator of the “doctor blade” type: then said solvent is left to evaporate. Said solvent may be selected, for example, from: hydrocarbons such as, for example, 1,2-dichloromethane, toluene, hexane; ketones such as, for example, acetone, acetylacetone; or mixtures thereof.

In the case when the transparent matrix is of the vitreous type, said at least one photoluminescent compound may be dissolved in at least one suitable solvent (which may be selected from those reported above) obtaining a solution that is deposited on a plate of said transparent matrix of the vitreous type, forming a film comprising said at least one photoluminescent compound working, for example, by using a film applicator of the “doctor blade” type: then said solvent is left to evaporate.

Alternatively, a plate comprising said at least one photoluminescent compound and said polymer obtained as described above, by dispersion in the melt, or addition in the bulk, and subsequent “casting”, may be held between two plates of said transparent matrix of the vitreous type (“a sandwich”) working according to the known so-called lamination technique.

For the purpose of the present invention, said luminescent solar concentrator (LSC) may be made in the form of a plate by addition in the bulk and subsequent “casting”, as described above.

According to a preferred embodiment of the present invention, said photoluminescent compound may be selected, for example, from photoluminescent compounds having a range of absorption ranging from 290 nm to 700 nm, preferably ranging from 300 nm to 650 nm, and a range of emission ranging from 390 nm to 900 nm, preferably ranging from 400 nm to 850 nm.

According to a preferred embodiment of the present invention, said photoluminescent compound may be selected, for example, from benzothiadiazole compounds such as, for example, 4,7-di-(thien-2′-yl)-2,1,3-benzothiadiazole (DTB), or mixtures thereof; acene compounds such as, for example, 9,10-diphenylanthracene (DPA), or mixtures thereof; perylene compounds such as, for example, the compounds known by the trade name Lumogen® from BASF, or mixtures thereof; or mixtures thereof. Preferably, said photoluminescent compound may be selected from 4,7-di-2-thienyl-2,1,3-benzothiadiazole (DTB), 9,10-diphenylanthracene (DPA), or mixtures thereof, even more preferably it is 4,7-di-(thien-2′-yl)-2,1,3-benzothiadiazole (DTB). Benzothiadiazole compounds are described, for example, in Italian patent application MI2009A001796. Acene compounds are described, for example, in international patent application WO 2011/048458.

According to a preferred embodiment of the present invention, said photoluminescent compound may be present in said luminescent solar concentrator (LSC) in an amount ranging from 0.1 g per unit area to 2 g per unit area, preferably ranging from 0.2 g per unit area to 1.5 g per unit area, said unit area being referred to the surface area of the matrix of transparent material expressed in m².

For the purpose of the present invention, any type of micrometric or sub-micrometric dielectric structure may be used that is able to induce diffusion and/or diffraction of sunlight, preferably diffraction, within said luminescent solar concentrator (LSC), in a spectral range where there is no absorption of said photoluminescent compound. According to a preferred embodiment of the present invention, said micrometric or sub-micrometric dielectric structure may comprise a material of spherical shape that may be organized in ordered and/or partially ordered, one-dimensional or two-dimensional dielectric lattices, preferably in triangular 2D lattices or in holographic 1D lattices. According to a preferred embodiment of the present invention, said material of spherical shape may comprise spheres that may have a diameter ranging from 300 nm to 800 nm, preferably ranging from 400 nm to 700 nm. It should be noted that said diameter is comparable with the wavelengths of sunlight.

According to a preferred embodiment of the present invention, said micrometric or sub-micrometric dielectric photonic structure may comprise one or more layers, preferably from 1 to 10 layers, more preferably from 1 to 5 layers, of spherical colloids, preferably of spherical colloids of polystyrene (PS), deposited on the upper face of a rigid support, preferably of a thin glass that is transparent to sunlight. Preferably, said glass may have a thickness ranging from 85 μm to 400 μm, preferably ranging from 100 μm to 200 μm. Said micrometric or sub-micrometric dielectric photonic structure may be prepared by techniques known in the art. For example, said micrometric or sub-micrometric dielectric photonic structure may be prepared by spontaneous assembly of said spherical colloids, for example of spherical colloids of polystyrene (PS), by the technique described by Robbiano V. et al., in “Advanced Optical Materials” (2013), Vol. 1, p. 389-396; or by the spin-coating technique as described by Venkatesh S. et al., in “Langmuir” (2007), Vol. 23, No. 15, p. 8231-8235. Said techniques make it possible to obtain micrometric or sub-micrometric dielectric photonic structures having a varying degree of packing of said spherical colloids.

For the purpose of the present invention, said one or more layers of spherical colloids may be obtained from a suspension of spherical colloids of polystyrene (PS) (for example, but not exclusively, having a concentration of 2.6 mg/ml in a 50 vol % mixture of water and ethanol) that is then deposited, in one or more layers, on thin glass by the technique described by Robbiano V. et al., in “Advanced Optical Materials” (2013), Vol. 1, p. 389-396.

It should be noted that, for the purpose of the present invention, in the case when said micrometric or sub-micrometric dielectric photonic structure comprises several layers of spherical colloids of polystyrene (PS), said layers may be characterized by a variable degree of order in the plane (presence of disorder) and may be prepared with suspensions having different characteristics and with different composition.

According to a preferred embodiment of the present invention, said micrometric or sub-micrometric dielectric photonic structure may cover, partially or completely, preferably completely, the upper face and/or the lower face, preferably the upper face, of said luminescent solar concentrator (LSC).

According to a preferred embodiment of the present invention, said micrometric or sub-micrometric dielectric photonic structure may be coupled to the upper face and/or to the lower face of said luminescent solar concentrator (LSC) by a suitable optical gel. Said optical gel must possess a refractive index that allows good optical coupling and it may be selected, for example, from transparent silicone oils and greases, epoxy resins. According to a further embodiment of the present invention, said micrometric or sub-micrometric dielectric photonic structure may be applied on the upper face of a thin, flexible substrate (for example, a polystyrene substrate) and subsequently coupled to the upper face and/or to the lower face of said luminescent solar concentrator (LSC) by a suitable optical gel. Said optical gel may be selected from those reported above. According to a further embodiment of the present invention, said micrometric or sub-micrometric dielectric photonic structure may comprise one or more layers of spherical colloids, preferably of polystyrene (PS), that are formed directly on said luminescent solar concentrator (LSC).

Alternatively, said micrometric or sub-micrometric dielectric photonic structure, rather than being prepared and/or applied and/or grown once, may be prepared/applied/grown in components of smaller dimensions than those of the luminescent solar concentrator (LSC) and composed there like a mosaic.

According to a further embodiment of the present invention, several photovoltaic cells may be positioned on the outside of at least one side of said luminescent solar concentrator (LSC), preferably said photovoltaic cells may cover partially, more preferably completely, the outer perimeter of said luminescent solar concentrator (LSC).

For the purpose of the present description and of the claims that follow, the term “outer perimeter” means the four external sides of said luminescent solar concentrator (LSC). For the purpose of increasing the light absorbed by said luminescent solar concentrator (LSC), it is possible to put reflective mirrors on at least part of the outer perimeter of said luminescent solar concentrator (LSC).

According to a further preferred embodiment of the present invention, at least one reflective mirror may be put on at least part of the outer perimeter of said luminescent solar concentrator (LSC). Said reflective mirror may be made of metallic material (for example, aluminium, silver), or of dielectric material (for example, Bragg reflectors). It should be noted that sides having one or more photovoltaic cells, or completely covered with one or more photovoltaic cells, and sides having only one or more reflective mirrors or completely covered with one or more reflective mirrors, may alternate on said outer perimeter. Or, alternatively, one or more photovoltaic cells and one or more reflective mirrors may alternate on said outer perimeter.

Said one or more photovoltaic cells may be brought into contact with said luminescent solar concentrator (LSC) by means of a suitable transparent optical gel. Said optical gel may be selected from those reported above.

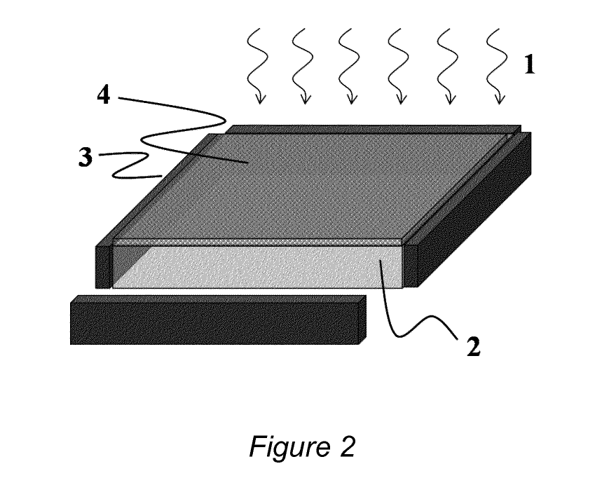

The hybrid concentrated photovoltaic device objecy of the present invention may be held together by a suitable frame made of metallic material, for example, aluminium. The present invention will now be illustrated in greater detail with an embodiment referring to FIG. 2 reported below.

In particular, FIG. 2 shows a hybrid concentrated photovoltaic device comprising a luminescent solar concentrator (LSC) (2) of square shape comprising at least one photoluminescent compound [e.g., 4,7-di-(thien-2′-yl-2,1,3-benzothiadiazole (DTB)], with photovoltaic cells (3) coupled optically to its lateral faces (in the case of FIG. 2: four photovoltaic cells, one on each lateral face, each lateral face being completely covered by a photovoltaic cell). A dielectric photonic structure [e.g., a sub-micrometric dielectric photonic structure of spherical colloids of polystyrene (PS)] (4) is applied optically on the upper face of said luminescent solar concentrator (LSC) (2), for the purpose of diffusing and/or diffracting a portion of the incident sunlight (1) within said luminescent solar concentrator (LSC) (2). Said diffused and/or diffracted light reaches the lateral faces of said luminescent solar concentrator (LSC) (2), and is absorbed by the photovoltaic cells (3), producing current.

For the purpose of better understanding of the present invention and for implementation thereof, some illustrative, non-limiting examples thereof are reported below.

### EXAMPLE 1 (COMPARATIVE)

Photovoltaic Device Comprising a Conventional Luminescent Solar Concentrator (LSC) (Devoid of Photonic Structure)

Four silicon photovoltaic cells IXYS-KXOB 22-12×1 each having a surface area of 1.2 cm² were placed on the four external sides of a plate of Altuglas VSUVT 100 polymethyl methacrylate (PMMA) (dimensions 22×22×6 mm) obtained by addition in the bulk of 100 ppm of 4,7-di-(thien-2′-yl)-2,1,3-benzothiadiazole (DTB) (obtained as described in Italian patent application M12009A001796) and subsequent casting.

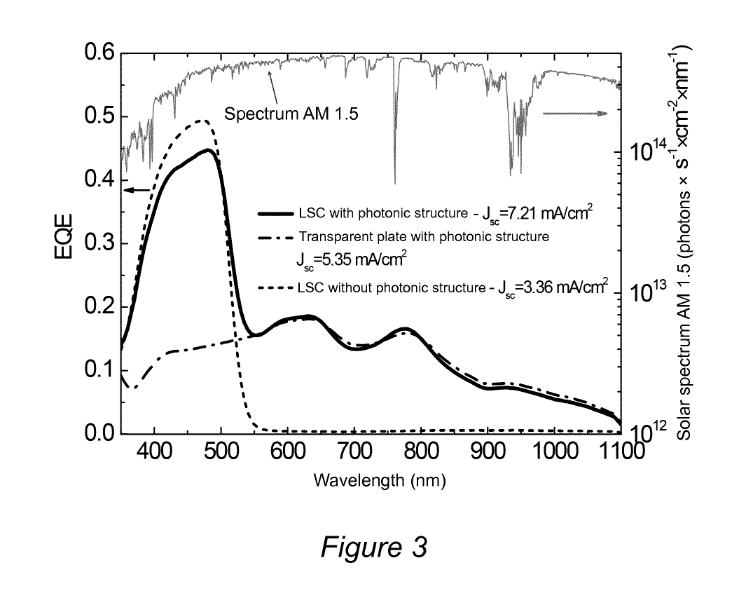

The external quantum efficiency (EQE) of said conventional luminescent solar concentrator (LSC) (devoid of photonic structure) was measured in the spectral range ranging from 350 nm to 1100 nm using the experimental equipment described in the article of Bozzola A. et al., in “Proceedings of the 26th European Photovoltaic Conference and Exhibition” (2011), Hamburg, Germany, p. 259-263: the result obtained is reported in FIG. 3.

As may be seen from the curve reported in FIG. 3, the external quantum efficiency (EQE) of said photovoltaic device extends over the spectral range of absorption of 4,7-di-(thien-2′-yl)-2,1,3-benzothiadiazole (DTB), i.e. from about 350 nm to about 550 nm, and has a maximum at λ=475 nm. The incident photons with wavelength greater than 550 nm are not utilized by the aforementioned photovoltaic device.

Once the external quantum efficiency (EQE) of said photovoltaic device had been measured, the short-circuit current density (J_{sc}) supplied by said device (per unit area) was calculated from the following equation (1):

$${J}_{sc} = e {\int }_{350 nm}^{1100 nm} EQE ( λ ) {ϕ}_{AM 1.5} ( λ ) d λ \qquad ( 1 )$$

in which:
e: denotes the elementary electric charge (equal to 1.6×10⁻¹⁹ C);
φ_{AM1.5}: denotes the flux AM 1.5 G of incident photons (expressed in units of photons×s⁻¹×cm⁻²×nm⁻¹);
λ: denotes the wavelength of the solar radiation.

The following result was obtained for the aforementioned photovoltaic device: J_{sc}=3.36 mA/cm².

### EXAMPLE 2 (COMPARATIVE)

Photovoltaic Device Comprising a Plate of Transparent Material and Photonic Structure

Four silicon photovoltaic cells IXYS-KXOB 22-12×1 each having a surface area of 1.2 cm² were placed on the four external sides of a plate of Altuglas VSUVT 100 polymethyl methacrylate (PMMA) (dimensions 22×22×6 mm) devoid of the photoluminescent compound.

Subsequently, a photonic structure consisting of a layer of spherical colloids of polystyrene (PS) having a diameter d=574 nm and with a thin supporting glass, obtained as described hereunder, was coupled onto the upper face of said plate of polymethyl methacrylate.

The spherical colloids of polystyrene (PS) were obtained from a suspension of polystyrene (PS) having a concentration equal to 2.6 mg/ml in a 50 vol % mixture of water and ethanol, and were then placed on the upper face of a thin supporting glass (thickness≈100 μm, dimensions 22×22 mm) by the “floating” technique, working as described by Robbiano V. et al., in “Advanced Optical Materials” (2013), Vol. 1, p. 389-396.

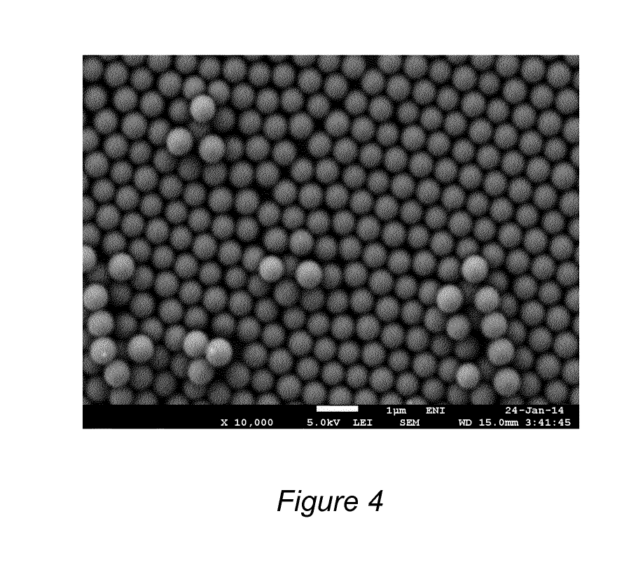

This photonic structure was submitted to scanning electron microscopy (SEM), with the Hitachi S-400, operating at 5.0 kV, to analyse the stratification of said spherical colloids of polystyrene (PS) and their packing in the plane: FIG. 4 shows the image obtained at 10000× of the monolayer of said spherical colloids of polystyrene (diameter of spheres d=574 nm).

As shown in FIG. 4, these spherical colloids of polystyrene tend to pack in the plane in an ordered manner, forming a triangular 2D lattice, with lattice pitch approximately equal to the diameter of said spherical colloids of polystyrene.

The lower face of the photonic structure thus obtained was brought into optical contact, by means of transparent silicone grease (CFG 1808), with the upper face of the polymethyl methacrylate (PMMA) plate as above, obtaining a photovoltaic device. As may be seen from the curve reported in FIG. 3, the external quantum efficiency (EQE) of said photovoltaic device, calculated as reported in Example 1, is greater than zero in the range that extends from about 350 nm to 1100 nm: the peaks present on said curve demonstrate the contribution of the diffraction of light by the aforementioned photonic structure.

Diffraction of light may occur either at the front, i.e. inside the polymethyl methacrylate (PMMA) plate, or at the back, i.e. in air. Using n_{PMMA} to denote the refractive index of polymethyl methacrylate (PMMA), which is equal to about 1.45, and taking into account that measurement of the external quantum efficiency (EQE) was performed in conditions of normal incidence, diffraction at the front [inside the polymethyl methacrylate (PMMA) plate] occurs for wavelengths below the “cut-off” wavelength calculated from equation (2):

λ≤d·n_{PMMA} (2)

whereas diffraction at the back (in air) occurs for wavelengths calculated from equation (3):

λ≤d (3)

in which d denotes the diameter of the spheres of the spherical colloids of polystyrene reported above.

Inserting the appropriate values in the aforementioned equations (2) and (3), it is found that diffraction at the front is permitted for λ<832 nm, whereas diffraction at the back is permitted for λ<574 nm: the external quantum efficiency (EQE) reaches its maximum in the range between these two limits.

It should be noted that below the “cut-off” of diffraction in polymethyl methacrylate (PMMA), i.e. for λ>832 nm, the incident light is diffused by the disorder present in the aforementioned photonic structure: the curve reported in FIG. 3 in fact shows tailing for values of λ>832 nm.

The short-circuit current density (J_{sc}) supplied by the aforementioned photovoltaic device (per unit area), calculated from equation 1 reported in Example 1, is as follows:

J_{sc}=5.35 mA/cm².

It may be seen from the data reported above that although the external quantum efficiency (EQE) of the aforementioned photovoltaic device never reaches the peak value attained by the photovoltaic device of Example 1, it nevertheless extends over a wider, more photon-rich spectral range, consequently generating a short-circuit current density (J_{sc}) about 60% greater than that of the photovoltaic device of Example 1: this is evident on comparing the curves of the external quantum efficiency (EQE) with the flux AM 1.5 G of incident photons reported in FIG. 3.

### EXAMPLE 3 (INVENTION)

Photovoltaic Device Comprising a Luminescent Solar Concentrator (LSC) and a Photonic Structure

A photonic structure obtained as described in Example 2 was coupled to a plate of Altuglas VSUVT 100 polymethyl methacrylate (PMMA) (dimensions 22×22×6 mm) obtained by addition in the bulk of 100 ppm of 4,7-di-(thien-2′-yl)-2,1,3-benzothiadiazole (DTB) (obtained as described in Italian patent application M12009A001796) and subsequent casting (i.e. said photonic structure was brought into optical contact, by means of transparent silicone grease (CFG 1808), with the upper face of the polymethyl methacrylate (PMMA) plate as above), and then four silicon photovoltaic cells IXYS-KXOB 22-12×1, each having a surface area of 1.2 cm², were applied on the four external sides.

As may be seen from the curve reported in FIG. 3, said photovoltaic device is able to utilize both the photoluminescence, and the diffusion and diffraction of light. In fact, the external quantum efficiency (EQE) of said photovoltaic device, calculated as reported in Example 1, shows behaviour similar to that of the photovoltaic device of Example 2 in the range that extends from about 350 nm to 550 nm, and outside of said range it shows behaviour similar to that of the photovoltaic device of Example 1.

The short-circuit current density (J_{sc}) supplied by the aforementioned photovoltaic device (per unit area), calculated from equation 1 reported in Example 1, is as follows:

J_{sc}=7.21 mA/cm².

It may be seen from the data reported above that although the external quantum efficiency (EQE) of the aforementioned photovoltaic device is less than the peak value attained by the photovoltaic device of Example 1, it nevertheless extends over a wider, more photon-rich spectral range, consequently generating a short-circuit current density (J_{sc}) about 115% greater than that of the photovoltaic device of Example 1: this is evident on comparing the curves of the external quantum efficiency (EQE) with the flux AM 1.5 G of incident photons reported in FIG. 3.

1. Hybrid concentrated photovoltaic device comprising:
(i) at least one luminescent solar concentrator (LSC) having the shape of polygonal, circular, or elliptical plate, comprising at least one photoluminescent compound having a spectral range of absorption and a spectral range of emission;
(ii) at least one micrometric or sub-micrometric dielectric photonic structure, optically coupled to said luminescent solar concentrator (LSC), said micrometric or sub-micrometric dielectric photonic structure being able to induce at least one of diffusion and diffraction of sunlight, within said luminescent solar concentrator (LSC), in a spectral range where there is no absorption of said photoluminescent compound;
(iii) at least one photovoltaic cell positioned on the outside of at least one side of said luminescent solar concentrator (LSC).

2. Hybrid concentrated photovoltaic device according to claim 1, wherein said luminescent solar concentrator (LSC) comprises a matrix of transparent material selected from transparent polymers: polymethyl methacrylate (PMMA), polycarbonate (PC), polyisobutyl methacrylate, polyethyl methacrylate, polyallyl diglycol carbonate, polymethacrylimide, polycarbonate ether, styrene acrylonitrile, polystyrene, methylmethacrylate styrene copolymers, polyether sulfone, polysulfone, cellulose triacetate, or mixtures thereof; transparent glasses: silica, quartz, alumina, titania, or mixtures thereof.

3. Hybrid concentrated photovoltaic device according to claim 1, wherein said photoluminescent compound is selected from photoluminescent compounds having a range of absorption ranging from 290 nm to 700 nm, and an interval of emission ranging from 390 nm to 900 nm.

4. Hybrid concentrated photovoltaic device according to claim 1, wherein said photoluminescent compound is selected from benzothiadiazole photoluminescent compounds; acenes compounds; perylene compounds; or mixtures thereof.

5. Hybrid concentrated photovoltaic device according to claim 1, wherein said photoluminescent compound is present in said luminescent solar concentrator (LSC) in an amount ranging from 0.1 g per unit area to 2 g per unit area, said unit area referring to the surface of the matrix of transparent material expressed in m².

6. Hybrid concentrated photovoltaic device according to claim 1, wherein said micrometric or sub-micrometric dielectric structure comprises a material of spherical shape organized in at least one of ordered and partially ordered, one-dimensional or two-dimensional dielectric lattices.

7. Hybrid concentrated photovoltaic device according to claim 6, wherein said material of spherical shape comprises spheres having a diameter ranging from 300 nm to 800 nm.

8. Hybrid concentrated photovoltaic device according to claim 1, wherein said micrometric or sub-micrometric dielectric photonic structure comprises at least one layer of spherical colloids, deposited on the upper face of a rigid support having a thickness ranging from 85 μm to 400 μm.

9. Hybrid concentrated photovoltaic device according to claim 1, wherein said micrometric or sub-micrometric dielectric photonic structure covers, partially or completely, at least one of the upper face and the lower face of said luminescent solar concentrator (LSC).

10. Hybrid concentrated photovoltaic device according to claim 1, wherein said micrometric or sub-micrometric dielectric photonic structure is coupled to at least one of the upper face and the lower face of said luminescent solar concentrator (LSC) by a suitable optical gel.

11. Hybrid concentrated photovoltaic device according to claim 1, wherein said micrometric or sub-micrometric dielectric photonic structure is applied on the upper face of a thin, flexible substrate and subsequently coupled to at least one of the upper face and the lower face of said luminescent solar concentrator (LSC) by a suitable optical gel.

12. Hybrid concentrated photovoltaic device according to claim 1, wherein said micrometric or sub-micrometric dielectric photonic structure comprises at least one layer of spherical colloids of polystyrene (PS), that are formed directly on said luminescent solar concentrator (LSC).

13. Hybrid concentrated photovoltaic device according to claim 1, in which several photovoltaic cells are positioned on the outside of at least one side of said luminescent solar concentrator (LSC), wherein said photovoltaic cells cover at least partially, the outer perimeter of said luminescent solar concentrator (LSC).

14. Hybrid concentrated photovoltaic device according to claim 1, in which at least one reflective mirror is put on at least part of the outer perimeter of said luminescent solar concentrator (LSC).
